(19) United States
(12) Patent Application Publication
(10) Pub. No.: US 2024/0004151 A1
(43) Pub. Date: Jan. 4, 2024

(54) EMBEDDED SILICON PHOTONICS CHIP IN A MULTI-DIE PACKAGE

(71) Applicant: Taiwan Semiconductor Manufacturing Company, Ltd., Hsinchu (TW)

(72) Inventor: Jen-Yuan Chang, Hsinchu (TW)

(21) Appl. No.: 18/446,424

(22) Filed: Aug. 8, 2023

Related U.S. Application Data
(62) Division of application No. 17/697,822, filed on Mar. 17, 2022.
(60) Provisional application No. 63/186,038, filed on May 7, 2021.

(51) Int. Cl. G02B 6/43; G02B 6/42

(52) U.S. Cl. CPC G02B 6/43; G02B 6/4245; G02B 6/4238

(57) ABSTRACT

A semiconductor package includes a base substrate structure having a top surface that includes conductive regions disposed in a dielectric region. The conductive regions are coupled to an interconnect structure. The semiconductor package also includes a first die bonded sideways on the base substrate structure. A side surface at an edge of the first die is bonded to the top surface of the base substrate structure. A front surface of the first die is perpendicular to the top surface of the base substrate structure. The first die includes a photonic device on a substrate of the first die, and the substrate includes an optical interface for coupling a back surface of the first die to an optical fiber.

### PRIORITY CLAIM AND CROSS-REFERENCE

This application is a divisional application of U.S. patent application Ser. No. 17/697,822, filed Mar. 17, 2022, which claims the benefit of U.S. Provisional Patent Application No. 63/186,038, entitled “VERTICAL SMALL OUTLINE INTEGRATED CIRCUIT WITH EMBEDDED SILICON PHOTONIC CHIP,” filed May 7, 2021, the disclosure of which are incorporated by reference herein in their entirety.

### BACKGROUND

Semiconductor dies can be electrically connected with other circuitry in a package substrate. The package substrate provides for electrical connection to other circuitry on a printed circuit board. Semiconductor dies can have different functions and are difficult to be processed using same semiconductor processing techniques, so they are manufactured separately. A large multi-functional device having high performance can be obtained by assembling multiple dies into the device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a structure of a semiconductor device, in accordance with some embodiments.

FIG. 2 is a cross-sectional view of a die group having a plurality of dies stacked on top of each other horizontally, in accordance with some embodiments.

FIG. 3 is a simplified 3D perspective view of the die group shown in FIG. 2, in accordance with some embodiments.

FIG. 4A is a simplified cross-sectional view of an example die-group structure having a sideway stacked die group, in accordance with some embodiments.

FIG. 4B is a cross-sectional view of an enlarged portion (indicated by a doted-line rectangle) of the multi-die structure 40 of FIG. 4A.

FIG. 5 is a cross-sectional view of an example three-dimensional (3D) die group structure, in accordance with some embodiments.

FIG. 6A shows an example of a photonic integrated die, in accordance with some embodiments.

FIG. 6B shows an example of a photonic device shown in FIG. 6A, in accordance with some embodiments.

FIG. 7 shows an example implementation of optical interfaces shown in FIG. 6B, in accordance with some embodiments.

FIGS. 8A-8C illustrate an example fabrication process/method for fabricating a waveguide in a photonic integrated multi-die package, in accordance with some embodiments.

FIG. 9 illustrates an example fabrication process/method for fabricating a photonic integrated multi-die package in accordance with some embodiments.

### DETAILED DESCRIPTION

The following disclosure provides many different embodiments or examples for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Prepositions, such as “on” and “side” (as in “sidewall”) are defined with respect to the conventional plane or surface being on the top surface of the wafer or substrate, regardless of the orientation of the wafer or substrate. The term “horizontal” is defined as a plane parallel to the conventional plane or surface of a wafer or substrate, regardless of the orientation of the wafer or substrate. The term “vertical” refers to a direction perpendicular to the horizontal as defined above, i.e., perpendicular to the surface of a substrate. The terms “first,” “second,” “third,” and “fourth” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

There are many packaging technologies to house the semiconductors such as the 2D fan-out (chip-first) IC integration, 2D flip chip IC integration, PoP (package-on-package), SiP (system-in-package) or heterogeneous integration, 2D fan-out (chip-last) IC integration, 2.1D flip chip IC integration, 2.1D flip chip IC integration with bridges, 2.1D fan-out IC integration with bridges, 2.3D fan-out (chip-first) IC integration, 2.3D flip chip IC integration, 2.3D fan-out (chip-last) IC integration, 2.5D (solder bump) IC integration, 2.5D (bump) IC integration, bump 3D IC integration, bump chiplets 3D IC integration, bumpless 3D IC integration, bumpless chiplets 3D IC integration, SoIC™ and/or any other packaging technologies. It should be understood various embodiments disclosed herein although are described and illustrated in a context of a specific semiconductor packaging technology, it is not intended to limit the present disclosure only to that packaging technology. One skilled in the art would understand those embodiments may be applied in other semiconductor technologies in accordance with principles, concepts, motivations, and/or insights provided by the present disclosure.

As used herein, chips and dies are used interchangeably and refer to pieces of a semiconductor wafer, to which a semiconductor manufacturing process has been performed, formed by separating the semiconductor wafer into individual dies. A chip or die can include a processed semiconductor circuit having a same hardware layout or different hardware layouts, same functions or different functions. In general, a chip or dies has a substrate, a plurality of metal lines, a plurality of dielectric layers interposed between the metal lines, a plurality of vias electrically connecting the metal lines, and active and/or passive devices. The dies can be assembled together to be a multi-chip device or a die group. As used herein, a chip or die can also refer to an integrated circuit including a circuit configured to process and/or store data. Examples of a chip, die, or integrated circuit include a field programmable gate array (e.g., FPGA), a processing unit, e.g., a graphics processing unit (GPU) or a central processing unit (CPU), an application specific integrated circuit (ASIC), memory devices (e.g., memory controller, memory), and the like.

In various embodiments, a semiconductor package is provided, where the semiconductor package includes a base substrate and first die bonded to a surface of the base substrate. In those embodiments, the first die is arranged on the base substrate such that a first surface of the first die is perpendicular to the surface of the base substrate. In those embodiments, the first die comprises a photonic device on a substrate of the first die, where the substrate includes an optical interface structure for coupling a second surface of the first die, the second surface being opposite to the first surface. In those embodiments, the optical interface structure is configured to receive a fiber and to facilitate transmitting and/or receiving optical signals via the fiber and through the first die. This novel semiconductor package thus provides an photonic capability to the first die.

In various embodiments, another die-group semiconductor package is provided. In those embodiments, the die-group semiconductor package comprises a first die group and a base substrate structure. In those embodiments, the first die group comprises multiple dies including a first die and a second die. The first die is bonded to the second die in the first die group, and both the first and second dies are bonded to the base die structure such that a substrate of the first die and a substrate of the second die are disposed sideway (as opposed planar) on the base substrate structure. In those embodiments, the first die comprises a photonic device on the substrate of the first die, where the substrate includes an optical interface structure for coupling another surface of the first die. In those embodiments, the optical interface structure is configured to receive a fiber and to facilitate transmitting and/or receiving optical signals via the fiber and through the first die and to the second die. This novel die-group semiconductor package thus provides a photonic capability to the first die group.

In various embodiments, a photonic capability is provided on one or more die groups in a semiconductor package. In those embodiments, at least one die group is stacked sideway on a bottom die group of the semiconductor package and that die group includes a photonic device capable of providing optical signals to dies within the group, to the bottom group, and/or one or more other dies in the semiconductor package (if the semiconductor package includes more than one die group on the bottom die group). Thus, in those embodiments, photonic capability is provided in the semiconductor package.

Die and Die Group Structure in Accordance with the Disclosure

In this section, an example individual die structure, an example die group structure are provided to illustrate various contexts where the present disclosure may be applied. It should be understood that the examples shown in this section are merely illustrative for understanding how the present disclosure may be applied in those examples. Thus, these examples should not be construed as being intended to limit the present disclosure. One skilled in the art will understand the present disclosure may be applied in other semiconductor packaging technologies wherever appropriate.

### An Example Individual Die Structure in Accordance with the Present Disclosure

FIG. 1 is a structure of a semiconductor device 10 according to some exemplary embodiments. One or more of such a semiconductor device may be arranged on an individual die in accordance with the present disclosure. Referring to FIG. 1, the semiconductor device 10 includes a substrate 101, an active region 102 formed on a surface of the substrate 101, a plurality of dielectric layers 103, a plurality of metal lines and a plurality of vias 104 formed in the dielectric layers 103, and a metal structure 105 in a top inter-metal layer 106. In an embodiment, the semiconductor device 10 also includes passive devices, such as resistors, capacitors, inductors, and the like. The substrate 101 can be a semiconductor substrate or a non-semiconductor substrate. For example, the substrate 101 may include a bulk silicon substrate. In some embodiments, the substrate 101 may include an elementary semiconductor, such as silicon or germanium in a crystalline structure, a compound semiconductor, e.g., silicon germanium, silicon carbide, gallium arsenic, gallium phosphide, indium phosphide, indium arsenide, and/or indium antimonide, or combinations thereof. Possible substrate 101 may also include a semiconductor-on-insulator (SOI) substrate. In an embodiment, the substrate 101 is a silicon layer of an SOI substrate. The substrate 101 can include various doped regions depending on design requirements, e.g., n-type wells or p-type wells. The doped regions are doped with p-type dopants, e.g., boron, n-type dopants, e.g., phosphorous or arsenic, or combination thereof. The active region 102 may include transistors. The dielectric layers 103 may include interlayer dielectric (ILD) and intermetal dielectric (IMD) layers. The ILD and IMD layers may be low-k dielectric layers which have dielectric constants (k values) smaller than a predetermined value, e.g., about 3.9, smaller than about 3.0, smaller than about 2.5 in some embodiments. In some other embodiments, the dielectric layers 103 may include non-low-k dielectric materials having dielectric constants equal to or greater than 3.9. The metal lines and vias may include copper, aluminum, nickel, tungsten, or alloys thereof.

An Example Group Die Structure in Accordance with the Present Disclosure

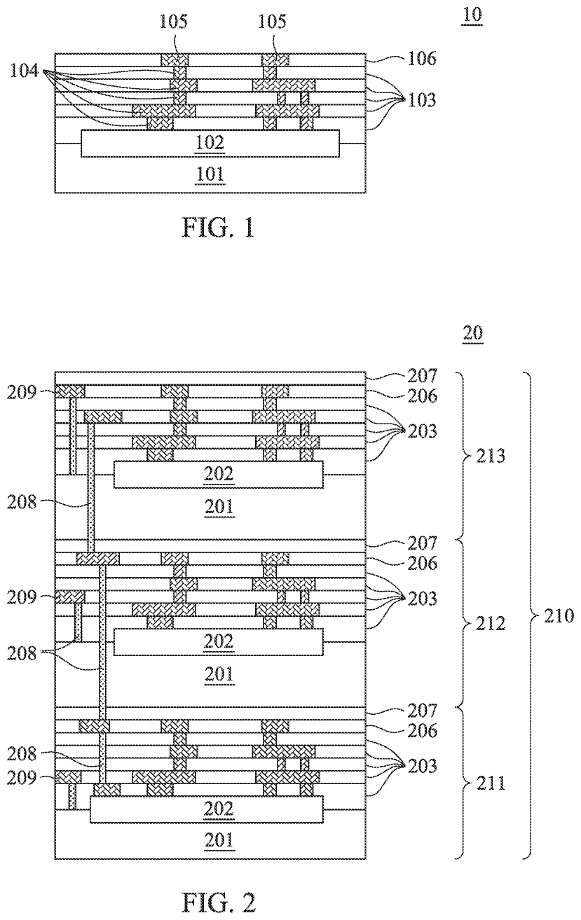

FIG. 2 is a cross-sectional view of a die group 20 having a plurality of dies stacked on top of each other horizontally. Referring to FIG. 2, the die group 20 includes a stacked die structure 210 including a plurality of dies 211, 212, and 213 stacked on top of each other in a substantially horizontal arrangement. As shown, in this example, each of the dies 203 in the die group includes a semiconductor device similar to the semiconductor device 10 described and illustrated in connection with FIG. 1. It should be understood although 3 dies are shown to be in the stacked die structure 210, this is not intended to be limiting. One skill in the art will understand that a stacked die structure in accordance with the present disclosure can include more or less number of dies than those shown in FIG. 2.

As can be seen, in this example, the stacked dies in the stacked die structure 210 are bonded to each other through bonding members 214. In some implementations, the bonding members 214 include hybrid bonding films. However, this is not intended to be limiting. It is understood that the bonding members 214 in accordance with the present disclosure do not have to include hybrid bonding films. For example, it is contemplated that the bonding members 214 may include micro bumps, solder balls, metal pads, and/or any other suitable bonding structures.

As also can be seen, each of the stacked dies 211, 212, and 213 includes a substrate 201, an active region 202 formed on a surface of the substrate 201, a plurality of dielectric layers 203, a plurality of metal lines and a plurality of vias 204 formed in the dielectric layers 203, and a passivation layer 207 on a top inter-metal layer 206. In an embodiment, a stacked die can also include passive devices, such as resistors, capacitors, inductors, and the like. The substrate 201 can be a semiconductor substrate or a non-semiconductor substrate. For example, the substrate 201 may include a bulk silicon substrate. In some embodiments, the substrate 201 may include an elementary semiconductor, such as silicon or germanium in a crystalline structure, a compound semiconductor, e.g., silicon germanium, silicon carbide, gallium arsenic, gallium phosphide, indium phosphide, indium arsenide, or combinations thereof. Possible substrate 201 may also include a semiconductor-on-insulator (SOI) substrate. In an embodiment, the substrate 201 is a silicon layer of an SOI substrate. The substrate 201 can include various doped regions depending on design requirements, e.g., n-type wells or p-type wells. The doped regions are doped with p-type dopants, e.g., boron, n-type dopants, e.g., phosphorous or arsenic, or combination thereof. The active region 102 may include transistors. The dielectric layers 203 may include interlayer dielectric (ILD) and intermetal dielectric (IMD) layers. The ILD and IMD layers may be low-k dielectric layers which have dielectric constants (k values) smaller than a predetermined value, e.g., about 3.9, smaller than about 3.0, smaller than 2.5 in some embodiments. In some other embodiments, the dielectric layers 203 may include non-low-k dielectric materials having dielectric constants equal to or greater than 3.9. The metal lines and vias may include copper, aluminum, nickel, tungsten, or alloys thereof.

In this example, the die group 20 includes through silicon vias (TSVs) or through oxide vias (TOVs) 208 configured to electrically connect the metal lines in the stacked dies 211, 212, and 213 with each other. In implementation, an individual TSV/TOV 208 may include copper, aluminum, tungsten, alloys thereof, and/or any other suitable materials. TSV/TOVs 208 are arranged in this example to facilitate electronic communication between and among stacked dies 211, 212 and 213. However, it is understood that in some other semiconductor packaging technologies where the present disclosure applies, TSV/TOVs may not be present and thus the TSV/TOVs 208 shown in this example shall not be construed as being intended to limit the present disclosure.

In this example, each of the stacked dies 211, 212, and 213 also includes a side metal interconnect structure 209 on a sidewall of the stack dies. The side metal interconnect structure 209 may include one or more metal wirings extending through an exposed surface of the plurality of dielectric layers 203. The side metal interconnect structure 209 may be formed at the same time as the metal layers and exposed to the side surface of the die group 20 after the different dies 211, 212, and 213 have been bonded together and the side surface is polished by a chemical mechanical polishing (CMP) process.

In some embodiments, the die group 20 can be formed by bonding a plurality of wafers together using fusion bonding, eutectic bonding, metal-to-metal bonding, hybrid bonding processes, and the like. A fusion bonding includes bonding an oxide layer of a wafer to an oxide layer of another wafer. In an embodiment, the oxide layer can include silicon oxide. In an eutectic bonding process, two eutectic materials are placed together, and are applied with a specific pressure and temperature to melt the eutectic materials. In the metal-to-metal bonding process, two metal pads are placed together, a pressure and high temperature are provided to the metal pads to bond them together. In the hybrid bonding process, the metal pads of the two wafers are bonded together under high pressure and temperature, and the oxide surfaces of the two wafers are bonded at the same time.

In some embodiments, each wafer may include a plurality of dies, such as semiconductor devices of FIG. 1. The bonded wafers contain a plurality of die groups having a plurality of stacked dies. The bonded wafers are singulated by mechanical sawing, laser cutting, plasma etching, and the like to separate into individual die groups that can be the die group as shown in FIG. 2.

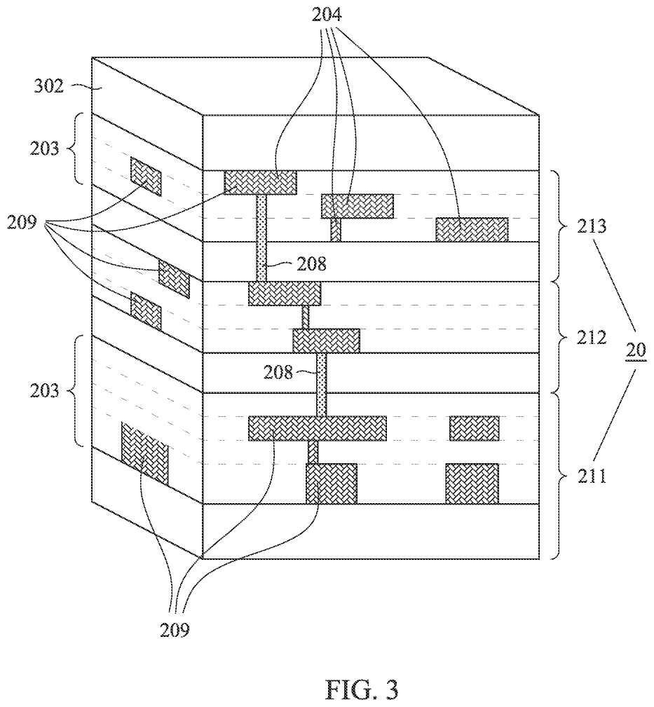

FIG. 3 is a simplified 3D perspective view of the die group 20 shown in FIG. 2. In particular, FIG. 3 shows the die group structure 20 includes a bonding layer 302 on a surface of the die group structure 20. In some embodiments, bonding layer 302 comprise an oxide material, e.g., silicon oxide. In some embodiments, the bonding layer 302 may include a plurality of bonding films. In various embodiments, the bonding layer 302 are configured to bond the die group 20 to a base structure in a semiconductor package structure which the die group 20 is part of. As will be described and illustrated in the next section, one example of using bonding layer 302 is in a sideway stacking of the die group 20 on the base structure.

### Sideway Stacking a Die Group

Attention is now directed to stacking of individual dies within a die group. In planar stacking, the individual dies in the die group are laid flat such that their substrates are faced towards (or away from) a planar base structure where the die group is located. An example of a planar stacking of the individual dies in the die group is shown in FIG. 2.

In some embodiments, multiple dies are packaged in sideway stacking. The individual dies are “stood” sideway against each other in the die group such that their substrates are placed sideway with respect to a base structure of a semiconductor package of which the die group is part. As a conceptual illustration, thus not intended to be limiting, sideway stacking of individual dies in a die group may be visualized as standing books between two book ends on a shelf, where the books are individual dies (a bottom cover of a given one of the books may be visualized as a substrate of that book), and shelf may be visualized as a base substrate where the die group is located. In contrast, in planar stacking, the books are piled on top of one another on the shelf.

An Example Sideway Stacked Die Group Structure

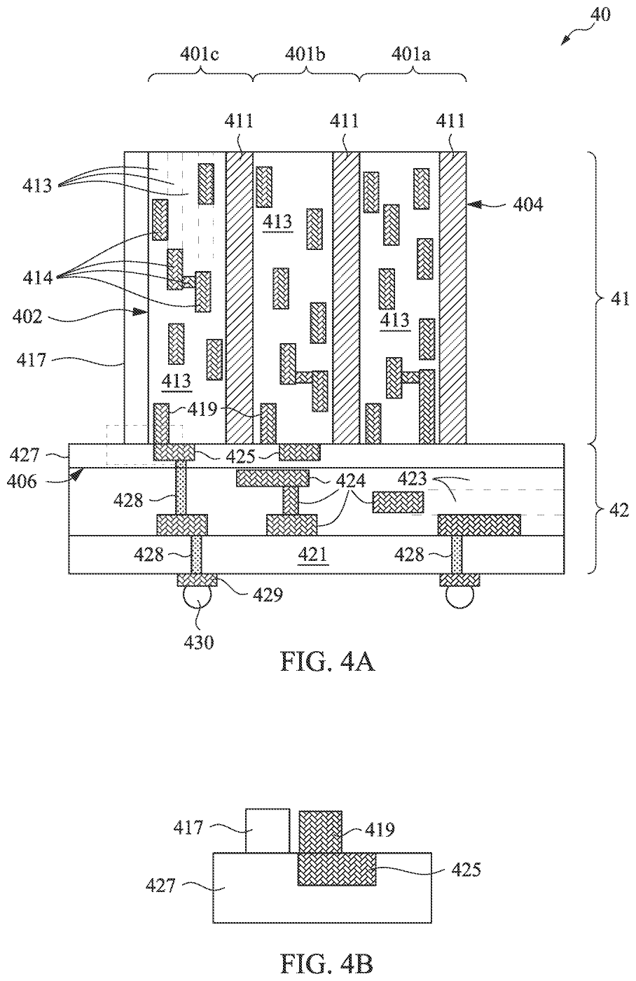

FIG. 4A is a simplified cross sectional view of an example die-group structure 40 having a sideway stacked die group according to an exemplary embodiment. FIG. 4A illustrates an example sideway stacking of individual dies in a die group in accordance various embodiments. Referring to FIG. 4A, the die-group structure 40 includes a first die group 41 having a first surface 402 and a second surface 404, and a second die group 42 having a surface 406 as shown. As also shown the first and second die groups 41 and 42 are disposed substantially perpendicular to each other. In this example, the first die group 41 includes a plurality of dies 401a, 401b, and 401c stacked next to each other. In this example, each of the dies 401a, 401b and 401c includes a substrate 411, a plurality of dielectric layers 413, a plurality of metal lines and vias 414 in the dielectric layers 413. In this example, the first die group 41 also includes a bonding layer 417 on the first surface 402, and a side metal structure 419 disposed on a side surface of the first die group 41. The bonding layer 417 includes an oxide material. In an embodiment, the bonding layer 417 is free of a metal interconnect structure. The first die group 41 may be similar or the same as the die group 20 of FIG. 2 shown in FIG. 3 so that a description of which will not be repeated herein for the sake of brevity.

In this example, the second die group 42 includes a substrate 421, a plurality of dielectric layers 423, a plurality of metal lines and vias 424 in the dielectric layers 423, a bonding layer 427 on the second upper surface of the substrate 421. The bonding layer 427 includes an oxide material. In an embodiment, the bonding layer 427 may be a hybrid passivation layer having a plurality of metal pads 425 in the oxide material. The second die group 42 also includes one or more through silicon vias and through oxide vias 428 electrically coupled to the metal structure 419 either directly or through the metal pad 425. In an embodiment, the second die group does not include active devices (e.g., transistors) or passive devices (resistors, diodes, inductors). In an embodiment, the substrate 421 can include active and/or passive devices formed therein. The substrate 421 can include doped or undoped silicon, an active layer of a semiconductor-on-insulator (SOI) substrate or other semiconductor materials, e.g., germanium, a compound semiconductor including silicon carbide, gallium arsenic, gallium phosphide, indium phosphide, indium arsenide, an alloy semiconductor including SiGe, GaAsP, AlGaAs, GaInAs, GaInP, or combinations thereof. Other substrates, such as multi-layered or gradient substrates, may also be used. In an embodiment, devices, such as transistors, diodes, capacitors, resistors, may be formed in the substrate and may be interconnected by interconnect structures by metallization patterns in one or more dielectric layers 423. In the example shown in FIG. 4A, a single substrate 421 is used for the second die group 42, but it is understood that the number is illustrative only and is chosen for describing the example embodiment and should not be limiting. That is, the second die group 42 can include a stack of dies stacked on top of each other.

As shown, in this example, the first die group 41 is attached to the second die group 42 with the first and second bonding layers 417, 427 and/or by the side metal structure 419 and metal pads 425 in the bonding layer 427. In some embodiments, the first die group 41 and the second die group 42 are bonded by fusion bonding, direct bonding, dielectric bonding, metal bonding, hybrid bonding, or the like. In the fusion bonding, the oxide surfaces of the bonding layers 417, 427 are bonded together. In the metal bonding, a metal surface of the side metal structure 419 and a metal surface of the metal pads 425 are pressed against each other at an elevated temperature, the metal inter-diffusion causes the bonding of the side metal structure 419 and the metal pads 425. In the hybrid bonding, the metal surface of the side metal structure 419 and the metal surface of the metal pads 425 are bonded together and the oxide surfaces of the bonding layers 417, 427 are bonded together. In some embodiments, the second die group 42 is a base die group or bottom die group configured to provide mechanical support and electrical wirings to the attached first die group 41. In various implementation, the first die group 41 may be referred to as a top die group, and the second die group 42 may be referred to as a bottom die group. In some embodiments, the second die group 42 may have a plurality of bond pads 429 on a lower surface of the substrate 421, each bond pad being electrically coupled to an under metal bump or micro bump 430. In an embodiment, the metal pads 425 have a surface coplanar with an upper surface of the bonding layer 427. In some embodiments, the multi-die structure 40 also includes an around die dielectric 433 layer encapsulating the first die group 41 and the second die group 42 after they are bonded together. In an embodiment, the around die electric 433 includes tetraethyl orthosilicate (TEOS), silicon oxide, and the like.

FIG. 4B is a cross-sectional view of an enlarged portion (indicated by a doted-line rectangle) of the multi-die structure 40 of FIG. 4A. Referring to FIG. 4B, oxide surfaces of the first bonding layer 417 and second bonding layer 427 are fusion bonded together. The bonding layers 417 and 427 each include an oxide material and function as bonding layers. In an embodiment, the metal structure 419 and the metal pad 425 are metal-to-metal bonded together. In an embodiment, each of the metal structure 419 and the metal pad 425 may include copper for a copper-to-copper bonding. In an embodiment, each of the metal structure 419 and the metal pad 425 may include aluminum for an aluminum-to-aluminum bonding. In an embodiment, each of the metal structure 419 and the metal pad 425 may include tin or tin alloy for a tin-to-tin or tin alloy bonding. In an embodiment, the metal structure 419 and the metal pad 425 function as interconnect layers. In an embodiment, the metal structure 419 and the metal pad 425 function as bonding layers, rather than interconnect layers. In an embodiment, the metal structure 419 and the metal pad 425 function as thermal dissipation layers to mitigate hot spots in the die group. In an embodiment, the metal structure 419 and the metal pad 425 are connected to a grounding plane for electromagnetic shielding of some functional devices of the die group. In an embodiment, the metal structure 419 and the metal pad 425 can have more than one of the functions described above. In an embodiment, the metal pad 425 may include a micro metal bump or a solder bump. The metal pads have a coefficient of thermal expansion (CTE) higher than that of the bonding layers (i.e., oxide bonding layers). The different CTEs can cause problems in bonding the bonding layers, such as warpage and breakage (chip cracking) of the second die group 42.

An Example of a Sideway Semiconductor Package

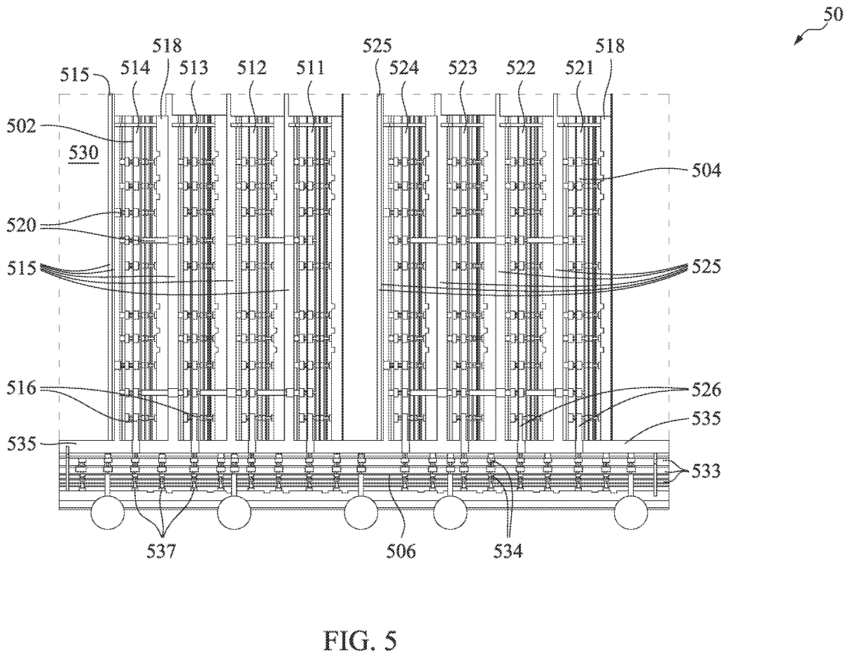

Attention is now directed to FIG. 5 where an example of semiconductor package is provided in accordance with the present disclosure. It should be understood the example provided in FIG. 5 is merely to illustrate how the present disclosure may be applied in this example, and thus is not intended to be limiting. For example, it should not be construed that the present disclosure is only applied to the semiconductor package shown in FIG. 5. One skilled in the art will understand the present disclosure can be applied to other semiconductor packaging, for example, as enabled by other figures and descriptions of the present disclosure and as well as their knowledge in semiconductor packaging.

FIG. 5 is a cross-sectional view of an example three-dimensional (3D) die group structure 50. Referring to FIG. 5, the 3D die group structure 50 includes a first die group 502 (denoted “Top die group 1”), a second die group 504 (denoted “Top die group 2”), and a third die group 506 (denoted “Bottom die group 1”). In this example, each of the first and second die groups 502 and 504 includes a plurality of dies. For example, the first die group includes a die 511, a die 512 a die 513, and a die 514. As can be seen, dies in the first die group 502 are stacked sideway as described and illustrate herein. As also can be seen, each of these dies includes a substrate, a plurality dielectric layers, and a plurality of metal lines and vias in the dielectric layers, similar to the semiconductor device 10 of FIG. 1. A plurality of TSV/TOVs 520 are arranged in the first die group 502 to provide electrical connections between the stacked dies, similar to those shown for die group 20 in FIGS. 2-3 and for die group 41 in FIGS. 4A-B.

Similarly, the second die group 504 includes a die 521, a die 522, a die 523, and a die 524 on. These dies in the second die group 504 are also stacked sideway as can be seen, and have similar structures to those in the first die group 502. As can be seen, the first die group 502 includes bonding members 515 on an outer surface of the first die group 502 and as well as within the first die group 502 (in between the dies 511-514 in this example). In an embodiment, the bonding members 515 are free of a metal interconnection structure. For example, the first die group includes the bonding members 515 disposed on the surface of the die 514 and free of a metal interconnect structure. As mentioned above, in some implementations, the bonding members 515 may include hybrid bonding films of Si, SiO2, Cu and/or any other suitable hybrid bonding film materials.

In this example, the second die group 504 includes bonding members 525 on an outer surface of the die and as well as within the second die group as shown. In implementation, the bonding members 525 may have a same or substantially similar structure to the bonding members 515. However, this is not intended to be limiting. It is understood that the bonding members 515 and 525 may have different structures among themselves.

In this example, the first die group 502 also includes a metal connection member 516 on a side surface of the first die group, and the second die group 504 also includes a metal connection member 526 on a side surface of the second die group. The metal connection members 516 and 526 are configured in this example for connecting the first die group 502 and the second die group 504 to a third die group 506. In implementation, the third die group 506 can function as a support substrate, a carrier substrate, an interposer or any other component for the die structure 50. In this example, the third die group 506 has a dimension greater than a total dimension of the first and second die groups 502 and 504. In some embodiments, the third die group 506 includes a substrate and wirings configured to provide electrical connections between the first and second die groups 502 and 504.

In this example, the third die group 506 includes a plurality of active devices 537 on the substrate, a plurality of dielectric layers 533 on the active devices, and a plurality of metal lines and vias 534 in the dielectric layers 533. In this example, the third die group includes a bonding member 535 having a planar surface configured to bond with the bonding layers 515 and 525 of the first and second die groups. In an embodiment, the bonding member 535 is a hybrid bonding member including an oxide material (e.g., silicon oxide) and a plurality of bond pads in the oxide material and configured to couple to the metal connection members 516 and 526 of the first and second die groups, respectively. In an embodiment, the third die group also includes a plurality of under metal bumps or micro bumps (denoted “bump”) on its lower surface. In an embodiment, the 3D die group structure 50 also includes an around die dielectric layer 530 overlying the first, second and third die group after the first and second die groups have been mounted or bonded to the third die group. The around die dielectric layer 530 includes TEOS or silicon oxide.

In some embodiments, the first die group 502 and the second die group 504 each is formed by bonding a plurality of wafers on top of each other, and a cutting process (plasma etch, mechanical sawing, laser cutting) is performed on the bonded wafers to separate the bonded wafers into individual bars, the bars are then polished and singulated to individual die groups. In an embodiment, the singulation process may be performed by mechanical sawing. In an embodiment, the singulation process may be performed using suitable techniques, e.g., plasma etching, laser cutting, to prevent cracking and chipping.

Referring to FIG. 5, as can be seen, the bonding members 515 and 525 are vertically disposed on an upper surface (main surface) of the bonding member 535 of the third die group 506 through a side surface (also referred to as edge surface) of the respective bonding members 515 and 525. It is understood that the edge surface of the bonding member is substantially flush with the side surface of the top die group within a manufacturing tolerance. Each of the first and second die groups 502 and 504 is electrically coupled to the third die group 506 through the respective connection members 516 and 526. In an embodiment, the connection member is the side metal interconnect structure 209 of FIG. 2 or the side metal structure 419 of FIGS. 4A and 4B. In an embodiment, the third die group may have one or more dies stacked on top of each other. In that embodiment, the one or more dies of the third die group are electrically connected to another circuitry on a printed circuit board (not shown) through the plurality of under metal bumps or micro bumps. In that embodiment, the dies in the third die group 506 are co-planar stacked as described and illustrated herein.

### Integrated Photonic Device in a Multi-Die Structure

In this section, novel structures of a photonic device integrated into a multi-die package are provided with examples. As mentioned above, these structures are provided merely for illustrating some examples of present disclosure and thus shall not be interpreted as limiting the present disclosure.

Photonic Device Integrated into a Die in a Multi-Die Package

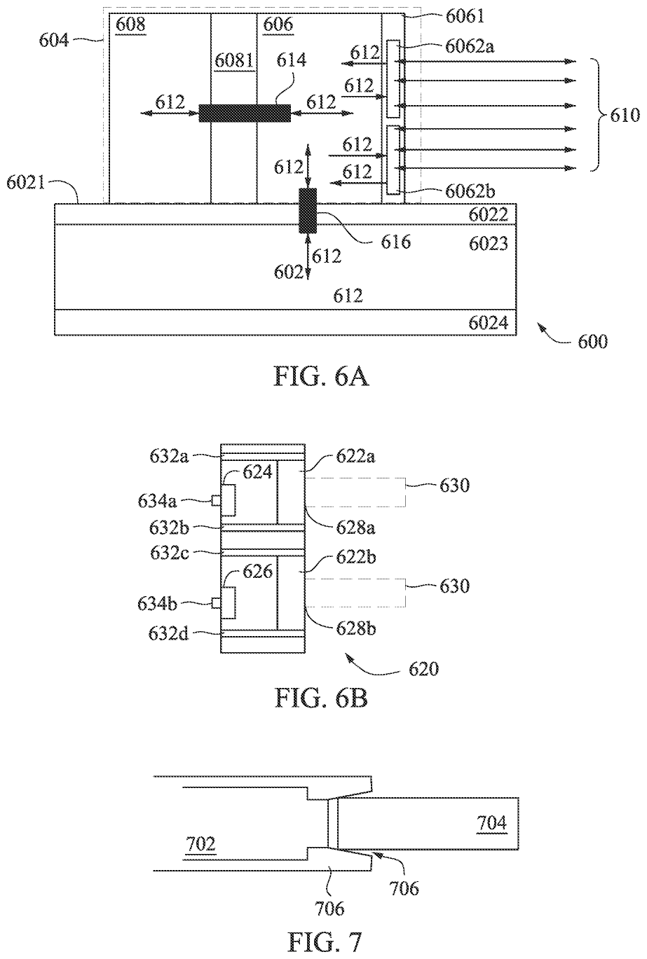

One insight behind the present disclosure is that when a die is stood up sideway on a base substrate in a multi-die package, the back surface of a substrate of this die is exposed (as compared to the die is stacked planar on another die or on the base substrate). As a result, the front surface, side surface, and back surface of the die are available for interconnect or interface structures. Some embodiments integrate a photonic capability into the die to make this a photonic integrated die—by arranging one or more photonic devices in an exposed back surface of the substrate of this die. An example of a photonic integrated die in accordance with the present disclosure is illustrated in FIG. 6A. This novel photonic integrated die thus can provide photonic capability to sideway stacked multi-die package, which is not possible when dies are stacked planar in a multi-die package.

Referring now to FIG. 6A, as can be seen, in this example, the multi-die package 600 comprises a base die structure 602 and a first die group 604 arranged on the base die structure 602. The first die group 604 in this example comprises a first die 606 and a second die 608. It should be understood, although only first die group 604 is shown in this example as being arranged on the base die structure 602, it is not intended to be limiting the present disclosure. In some other examples, more than one die group is arranged on the base die structure 602. In those examples, the die group(s) arranged on the base die structure 602, other than the first die group 604, does not necessarily have to be arranged in the same orientation (e.g., the sideway as shown in this example) as the first die group 604.

As can be seen, the base die structure 602, in this example, includes an active region 6022, a dielectric region 6023, and a substrate 6024. The base die structure 602, in other examples, can include components/elements more or less than those shown in this example. In implementation, the active region 6022 can comprise one or more interconnect structures, and the dielectric region 6023 can comprise one or more conductive regions. Example implementations of base die structure 602 are shown in FIG. 4A and FIG. 5. For instance, in FIG. 4A, the die group 42 can be understood as an example implementation of base die structure 602, where the metal pads 425 can be understood as interconnect structures and vias 424 can be understood as conductive regions.

As can be seen, in this example, the first die group 604 is bonded on top surface 6021 of the base die structure 602 sideway. The first die 606 and second die 608 in the first die group 604 are bonded to the top surface 6021 sideway as shown. It should be understood although only the first and second dies 606 and 608 are shown as being in the first die group 604, it is not intended to be limiting. In some other examples, the first die group 604 may include more or less dies. In examples where more than two dies are included in the first die group 604, the die(s), other than the first and second dies 606, 608 shown in this example, may be arranged in the same or different orientation as that of the first and second dies 606, 608.

As shown, the first die 606 and the second die 608 each includes a substrate 6061 and 6081 respectively. Attention is now directed to substrate 6061 of the first die 606. In this example, two photonic devices, 6062a and 6062b, are shown as included in substrate 6061. As shown, each of the photonic devices, 6062a and 6062b is configured to receive and/or transmit optical signals 610. As also shown, each of the photonic devices, 6062a and 6062b is configured to convert received optical signals 610 to corresponding electrical signals 612, and to convert electrical signals 612 to corresponding optical signals 610.

As still shown, the first die 606 includes an electrical coupling 614 to the second die 608, and an electrical coupling 616 to the base die structure 602. In implementation, the electrical coupling 614 and/or 616 may comprise TSV/TOV, interposer, metal pads, and/or another appropriate components. In this example, as shown, the electrical coupling 614 is used to communicate electrical signals 612 between the first and second dies 606, 608, and the electrical coupling 616 is used to communicate electrical signals 612 between the first die 606 and base die structure 602. It should be understood although only electrical couplings 614 and 616 are shown in this example as being included in the first die 606, this not intended to be limiting. In some other examples, more or less electrical couplings may be included in first die 606 than those shown in FIG. 6A.

Attention is now directed to FIG. 6B, where an example of a photonic device 6062a and 6062b shown in FIG. 6A is provided. It will be described with reference to FIG. 6A. As shown, in this example, the photonic device 620, which can be integrated into the sideway stacked die 606 in the multi-die package 600, includes waveguide sections 622a and 622b. In various implementations, individual silicon waveguide sections, such as 622a and 622b, in the substrate 6061 of the die 606 can comprise nitride. Silicon waveguides with nitride have a lower signal propagation loss than silicon waveguides without nitride, and can be used to transmit optical signals over relatively longer distances compared to silicon waveguides without nitride. In some implementations, an individual waveguide section such as 622a can include a spatial filter structure configured to modulate laser beams for transmission through fiber 630.

It should be understood although two waveguide sections 622a and 622b are shown in this example as being included in photonic device 620, this is not intended to be limiting. In some other examples, a photonic device embedded in a sideway stacked die in accordance with the present disclosure can have more or less waveguide sections than those shown in FIG. 6B.

As also shown in FIG. 6B, cladding layers 632a-d are formed around the waveguide sections 622a and 622b. The cladding layers 632a-d can prevent or reduce leakage of optical signals (such as optical signals 610 shown in FIG. 6A) into substrate 6061 of the die 606. U.S. Pat. No. 10,746,923 describes and illustrates some implementations for forming cladding layers 632a-d. It should be understood although four cladding layers are shown in this example as being included in photonic device 620, this is not intended to be limiting. In some other examples, a photonic device embedded in a sideway stacked die in accordance with the present disclosure can have more or less cladding layers than those shown in FIG. 6B.

As still shown in FIG. 6B, the photonic device 620 in this examples includes optical interfaces 628a and 628b configured to receive fibers 630 and to facilitate communication of optical signals 610 through the fibers 630. The fibers 630, in various embodiments, may be coupled to one or more components external to die 606, die group 604, and/or the multi-die package 600.

An example implementation of optical interfaces 628a and 628b are shown in FIG. 7. As shown in FIG. 7, the optical interface 706 is configured to be at an end of a waveguide section 702 and to receive a fiber 704. As shown, a shape of optical interface 706, in this example, is defined by cladding layer 706 around the waveguide section 702. In the example, the shape of the optical interface 706 is configured in a stepped manner that a size of the optical interface is tapered gradually from a fiber end towards a waveguide end of the optical interface 706. This design of optical interface 706 can help prevent or reduce potential impact of fiber 704 to the silicon substrate (such as 6061 shown in FIG. 6A) where the photonic device (such as photonic device 620) is embedded.

Attention is now directed back to FIG. 6B. The photonic device 620, in this example, includes a laser die 624 and an optical sensor 626. The laser die 624 is configured to provide a laser source for the photonic device 620. The laser die 624 is configured to emit laser beams to towards the waveguide section 622a, which can collect and/or combine the laser beams for transmission through the fiber 630 using optical interface 628a. The laser die 624 can be configured to modulate and/or generate the laser beams. In some implementations, the laser die 624 can be configured to covert electrical signals received through interconnect 634a into one or more laser beams. In various implementations, the laser die 624 comprises laser emitting diodes and one or more circuits to achieve these operations.

The optical sensor 626 is configured to detect optical signals received from the fiber 630 through optical interface 628b via waveguide section 622b. The optical sensor 626 is configured to convert the received optical signals to electrical signals for transmission within die 606, to die 608 and/or to base die structure 602 through interconnect 634b. It should be understood although only one laser die 624 one optical sensor 626 are shown in this example as being included in the photonic device 620, this not intended to be limiting. In some other examples, more or less laser dies and optical sensors may be included in photonic device 620 than those shown in FIG. 6B.

### Fabricating a Waveguide in a Photonic Device Integrated Multi-Die Package

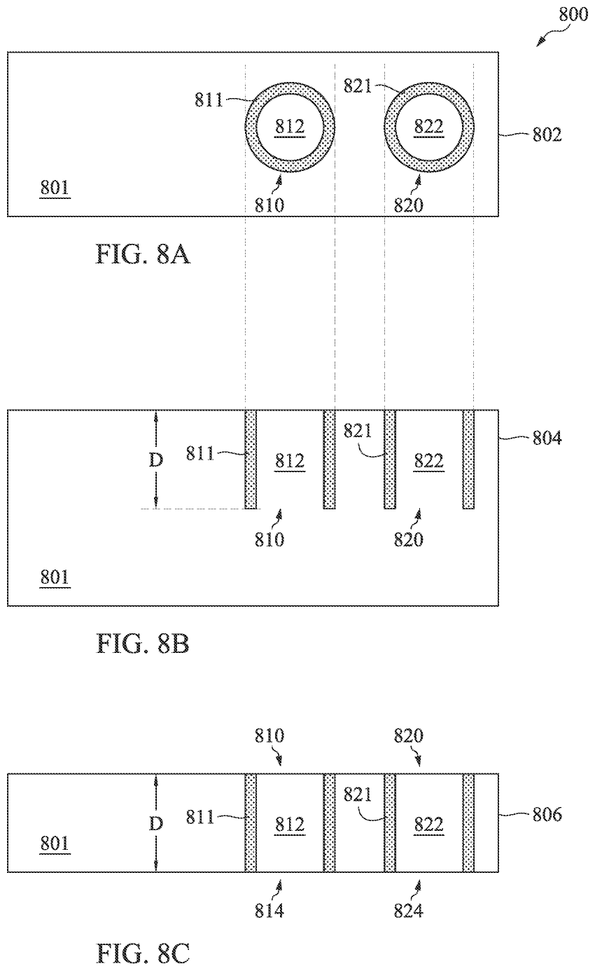

FIGS. 8A-8C illustrate an example fabrication process/method for fabricating a waveguide in a photonic integrated multi-die package, in accordance with some embodiments.

in accordance with the present disclosure.

FIG. 8A shows a top view of a substrate in a stage of fabricating a photonic die, and FIG. 8B shows a cross-sectional view of the substrate along a cut line A-A′, in accordance with some embodiments. As shown in FIGS. 8A and 8B, circular trenches 810 and 820 are formed in a substrate 801. In some embodiments, circular trenches 811 and 821 are filled with a dielectric material, such as silicon oxide or silicon nitride. Circular trenches 811 and 821 surround silicon core regions 812 and 822, respectively. In an example, trench 811 forms a cladding layer of waveguide 810, and silicon core region 812 forms the core of a waveguide 810. Similarly, trench 821 forms a cladding layer of waveguide 820, and silicon core region 822 forms the core of a waveguide 820.

As shown in FIG. 8B, circular trenches 811 and 821 extends into the substrate 801 to a depth D for the desired length of waveguides.

In FIG. 8C, the back side of substrate 801 is polish to remove a portion of the substrate to expose a back surface 814 of waveguide 810 and a back surface 824 of waveguide 820.

Next, an optical interface structure can be built at the back surface of a waveguide. An example is shown in FIG. 7, where the optical interface 706 is configured to be at an end of a waveguide section 702 and to receive a fiber 704.

### Fabricating a Photonic Device Integrated Multi-Die Package

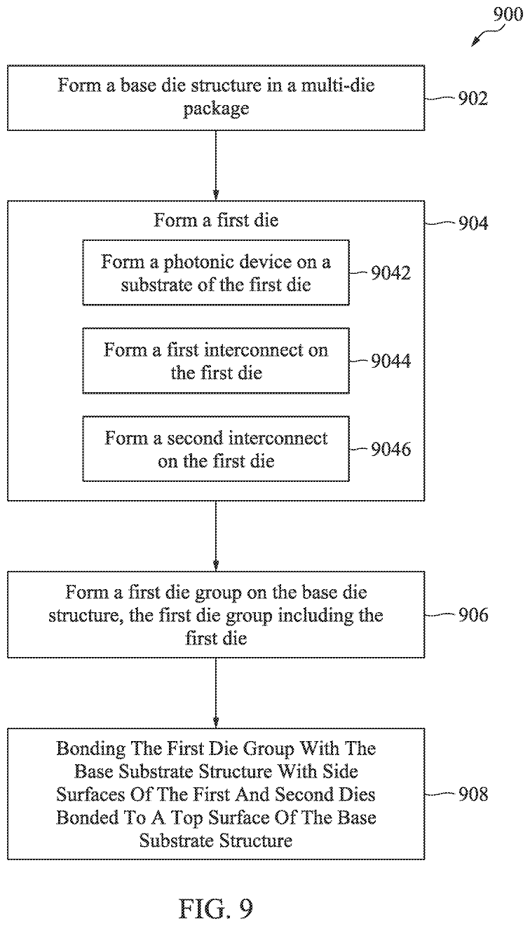

FIG. 9 illustrates an example fabrication process/method for fabricating a photonic integrated multi-die package in accordance with the present disclosure.

At 902, a base structure is formed for a multi-die package. In various implementation, the base structure has an active region, a dielectric region and a substrate. An example of the base structure formed at 902 is shown in FIG. 6A.

At 904, a first die is formed for the multi-die package. In various implementations, 904 includes one or more sub-operations described below.

At 9402, a photonic device is formed on a substrate of the first die as an integrated photonic device. An example photonic device is shown in FIG. 6B. In various implementations, 9402 involves forming such a photonic device on the substrate of the first die as shown in FIG. 6A. In those implementations, the photonic device formed at 9402 includes one or more waveguide sections, such as waveguide sections 622a and 622b shown in FIG. 6B, one or more cladding layers around the waveguide section, such as the cladding layers 632a-d shown in FIG. 6B, one or more optical interfaces, such as optical interfaces 628a and 628b shown in FIG. 6B, and/or any other components. In various implementation, the waveguide sections of the photonic device formed at 9042 are exposed by removing a portion of the substrate of the first die where the photonic device is located.

At 9044, a first interconnect is formed on the first die. An example of the first interconnect is shown at element 614 in FIG. 6A.

At 9046, a second interconnect is formed on the first die. An example of the second interconnect is shown at element 616 in FIG. 6A

At 906, a first die group is formed on the base die structure formed at 902. The first die group includes the first die formed at 904. In some embodiments, the first die group can include one or more other dies forming stacked structure with the first die.

At 908, the first die group is bonded with the base substrate structure with side surfaces of the first and second dies bonded to a top surface of the base substrate structure. The first group is formed on the base die structure such that the first die is stacked sideway as illustrated and described in FIGS. 4-6B.

In some embodiments, a semiconductor package includes a first die group and a base substrate structure. The first die group includes stacked first and second dies, and each die includes an integrated circuit formed on a semiconductor substrate of the die. Each die is characterized by a first surface that is a top surface of the integrated circuit; a second surface that is a bottom surface of the semiconductor substrate, the first surface being opposite to the second surface; and a side surface at an edge of the die and substantially perpendicular to the first surface and the second surface. The side surface includes conductive regions disposed in a dielectric region, the conductive regions coupled to an interconnect structure in the die. The first surface of the first die is bonded to the second surface of the second die. The first die includes a photonic device in the semiconductor substrate of the first die. The photonic device includes an optical interface structure for coupling to an optical fiber at the second surface of the first die and a waveguide section configured to facilitate transmission of an optical signal through optical interface. The base substrate structure includes a top surface that includes conductive regions disposed in a dielectric region, the conductive regions coupled to an interconnect structure in the base substrate structure. The first die group is bonded sideways on the base substrate structure, with the side surfaces of the first and second dies bonded to the top surface of the base substrate structure, and the first surfaces of the stacked dies are substantially perpendicular to the top surface of the base substrate structure. The first die is configured to provide an electrical coupling to the second die through first surface, an electrical coupling to the base substrate structure though the side surface, and optical coupling to the optical fiber through the second surface.

In some embodiments, a semiconductor package includes a base substrate structure having a top surface that includes conductive regions disposed in a dielectric region. The conductive regions are coupled to an interconnect structure. The semiconductor package also includes a first die bonded sideways on the base substrate structure. A side surface at an edge of the first die is bonded to the top surface of the base substrate structure. A front surface of the first die is perpendicular to the top surface of the base substrate structure. The first die includes a photonic device on a substrate of the first die, and the substrate includes an optical interface for coupling a back surface of the first die to an optical fiber.

In some embodiments, a method of fabricating a semiconductor package includes forming a base substrate structure having a top surface that includes conductive regions disposed in a dielectric region, and the conductive regions are coupled to an interconnect structure. The method also includes forming a first die. The process of forming the first die includes forming a photonic device on a substrate of the first die, wherein the photonic device includes a waveguide section; forming a first interconnect structure at a first surface of the first die; forming a second interconnect structure at a side surface of an edge of the first die; and removing a portion of the first substrate from a back side to expose the waveguide section at a second surface of the first die, the second surface being opposite to the first surface. The method further includes bonding the first die sideways on the base substrate structure, with the side surface of the first die bonded to the top surface of the base substrate structure and the first surface of the first die being perpendicular to the top surface of the base substrate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor package, comprising:
forming a base substrate structure, having a top surface that includes conductive regions disposed in a dielectric region, the conductive regions coupled to an interconnect structure;
forming a first die, including:
forming a photonic device on a first substrate of the first die, wherein the photonic device includes a waveguide section;
forming a first interconnect structure at a first surface of the first die;
forming a second interconnect structure at a side surface of an edge of the first die; and
removing a portion of the first substrate from a back side to expose the waveguide section at a second surface of the first die, the second surface being opposite to the first surface; and
bonding the first die sideways on the base substrate structure, with the side surface of the first die bonded to the top surface of the base substrate structure and the first surface of the first die being perpendicular to the top surface of the base substrate structure.

2. The method of claim 1, wherein bonding the first die sideways on the base substrate structure comprises a hybrid bonding process.

3. The method of claim 1, further comprising:
before bonding the first die sideways on the base substrate structure, polishing an edge of the first die to expose the second interconnect structure in the first die.

4. The method of claim 1, further comprising coupling an optical fiber to the waveguide section at the back side of the first die.

5. The method of claim 1, wherein forming the photonic device comprises forming a laser or optical sensor on the first substrate.

6. The method of claim 1, wherein forming the photonic device comprises bonding a laser or optical sensor on the first substrate.

7. The method of claim 3, wherein the second interconnect structure in the first die is electrically coupled to the interconnect structure of the base substrate structure.

8. A method of fabricating a semiconductor package, comprising:
forming a base substrate structure, the base substrate structure characterized by a top surface that includes a first conductive region and a second conductive region disposed in a dielectric region of the base substrate structure, the first conductive region and the second conductive region being electrically coupled to an interconnect structure of the base substrate structure;
forming a first die and a second die, wherein the each of the first die and the second die comprises:
a semiconductor substrate;
an integrated circuit formed on the semiconductor substrate;
a top surface of the integrated circuit;
a bottom surface of the semiconductor substrate, the top surface being opposite to the bottom surface; and
a side surface substantially perpendicular to the bottom surface and the top surface; and
a conductive region disposed in a dielectric region of the integrated circuit, the conductive regions being electrically coupled to an interconnect structure disposed in the integrated circuit;
bonding the top surface of the first die to the bottom surface of the second die to form a first die group; and
bonding, sideways, the first die group to the base substrate structure, the side surface of the first die being bonded to the top surface of the base substrate structure, with the conductive region of the first die being bonded to the first conductive region of the base substrate structure, and the side surface of the second die being bonded to the top surface of the base substrate structure, with the conductive region of the second die being bonded to the second conductive region of the base substrate structure.

9. The method of claim 8, wherein forming the first die further comprises:
forming a photonic device in the semiconductor substrate of the first die.

10. The method of claim 9, wherein forming the photonic device in the semiconductor substrate of the first die comprises:
forming an optical interface structure for coupling to an optical fiber at the bottom surface of the first die; and
forming a waveguide section configured to facilitate transmission of an optical signal through the optical interface.

11. The method of claim 10, wherein forming the photonic device in the semiconductor substrate of the first die further comprises:
forming cladding layers surrounding the waveguide section.

12. The method of claim 10, wherein the first die is configured to provide:
an electrical coupling to the second die through the top surface of the first die;
an electrical coupling to the base substrate structure though the side surface of the first die; and
an optical coupling to the optical fiber through the bottom surface of the first die.

13. The method of claim 8, wherein the conductive region of the first die is bonded to the first conductive region of the base substrate structure using hybrid bonding.

14. The method of claim 13, wherein the conductive region of the second die is bonded to the second conductive region of the base substrate structure using hybrid bonding.

15. The method of claim 8, wherein the bottom surface of the first die and the top surface of the second die are substantially perpendicular to the top surface of the base substrate structure.

16. A method of fabricating a semiconductor package, comprising:
forming a base substrate structure, the base substrate structure characterized by a top surface that includes a first conductive region and a second conductive region disposed in a dielectric region of the base substrate structure;
forming a first die, wherein the first die comprises:
a semiconductor substrate of the first die;
an integrated circuit of the first die formed on the semiconductor substrate of the first die;
a top surface of the integrated circuit of the first die;
a bottom surface of the semiconductor substrate of the first die, the top surface of the integrated circuit of the first die being opposite to the bottom surface of the semiconductor substrate of the first die; and
a side surface of the first die substantially perpendicular to the bottom surface of the semiconductor substrate of the first die and the top surface of the integrated circuit of the first die; and
a conductive region of the first die disposed at the side surface of the first die;
forming a second die, wherein the second die comprises:
a semiconductor substrate of the second die;
an integrated circuit of the second die formed on the semiconductor substrate of the second die;
a top surface of the integrated circuit of the second die;
a bottom surface of the semiconductor substrate of the second die, the top surface of the integrated circuit of the second die being opposite to the bottom surface of the semiconductor substrate of the second die; and
a side surface of the second die substantially perpendicular to the bottom surface of the semiconductor substrate of the second die and the top surface of the integrated circuit of the second die; and
a conductive region of the second die disposed at the side surface of the second die;
bonding the top surface of the first die to the bottom surface of-the second die to form a first die group; and
bonding, sideways, the first die group to the base substrate structure, the side surface of the first die being bonded to the top surface of the base substrate structure, with the conductive region of the first die being bonded to the first conductive region of the base substrate structure, and the side surface of the second die being bonded to the top surface of the base substrate structure, with the conductive region of the second die being bonded to the second conductive region of the base substrate structure.

17. The method of claim 16, wherein forming the first die further comprises:
forming a photonic device in the semiconductor substrate of the first die.

18. The method of claim 17, wherein forming the photonic device in the semiconductor substrate of the first die comprises:
forming an optical interface structure for coupling to an optical fiber at the bottom surface of the first die;
forming a waveguide section configured to facilitate transmission of an optical signal through the optical interface; and
forming cladding layers surrounding the waveguide section.

19. The method of claim 18, wherein the first die is configured to provide:
an electrical coupling to the second die through the top surface of the first die;
an electrical coupling to the base substrate structure though the side surface of the first die; and
an optical coupling to the optical fiber through the bottom surface of the first die.

20. The method of claim 16, wherein the conductive region of the first die is bonded to the first conductive region of the base substrate structure using hybrid bonding, and wherein the conductive region of the second die is bonded to the second conductive region of the base substrate structure using hybrid bonding.
